(19) United States
(12) Patent Application Publication
(10) Pub. No.: US 2008/0060832 A1
(43) Pub. Date: Mar. 13, 2008

(54) Multi-layer cable design and method of manufacture

(76) Inventor: Ali Razavi, Dallas, PA (US)

Correspondence Address: L. ZALE PATENT LAW OFFICE, 334 SOUTH FRANKLIN ST., WILKES-BARRE, PA, 18702, US

(21) Appl. No.: 11/895,746

(22) Filed: Aug. 27, 2007

Related U.S. Application Data
(60) Provisional application No. 60/840,566, filed on Aug. 28, 2006.

(51) Int. Cl. H01B 11/00; B44C 1/22; H01B 7/02; H05K 9/00; C23C 14/00

(52) U.S. Cl. 174/102 C; 204/471; 216/41; 427/458; 427/523

(57) ABSTRACT

A novel method of designing and fabricating flexible and lightweight cable [100] having a central conductor [110], a dielectric layer [130], an outer conductor [150] and an insulation coating [170] using thin film technology is disclosed. The dielectric layer [130] is ‘grown’ on dielectric layer [130] using electrophoretic deposition to a specified thickness, based upon its intended use. It may include nano-diamonds. Ion beam assisted deposition is used to metalize the cable dielectric layer [130]. This may be ion beam assisted sputtering, ion beam assisted evaporative deposition or ion beam assisted cathodic arc deposition. In an alternative embodiment, the outer conductor may be etched to provide greater flexibility, or to add a piezoelectric layer. The central conductor [110] may be created from dielectric fibers [113] which are metalized as described above. The piezoelectric layer added to create ultrasonic transducer cables.

### CROSS REFERENCE TO RELATED APPLICATIONS

This patent application is a continuation-in-part application and claims priority from U.S. Patent Application 60/840,566 filed Aug. 28, 2006 by the same inventor, Dr. Ali Razavi.

### BACKGROUND OF THE INVENTION

1. Field of the Invention

The present invention relates to a thin, lightweight and flexible electronic cable.

2. Discussion of Related Art

Electric and electronic wires or cables include one or more conductors with a dielectric insulation material electrically insulating them from the other conductors or other electrically conducting objects. Electric signals passing through the conductors tend to ‘bleed’ through the insulator and dissipate with distance. The greater the amount of dielectric, the less the dissipation.

Since wires are bundled with wires carrying different signals, there is the effect of “cross-talk” in which signals pass through the insulation and are picked up on adjacent wires.

Multiple-conductor cables also experience ‘cross-talk’ between their own conductors. Again, using more dielectric minimizes this cross-talk, however makes the cables thicker and mechanically more difficult to carry, flex and bend.

Coaxial cables have a central conductor and a tubular shield surrounding the central conductor. These provide greater shielding against cross-talk; however, these tend to be even mechanically cumbersome than cables which are not coaxial due to the geometry. The outer conductor is essentially a tube which must be bent in different directions and in many applications, repeatedly. Different sides of the tube have a different bending radii, causing bunching of the shield tube on the inner side of the bend.

An attempt to make a flexible lightweight coaxial cable is described in U.S. Pat. No. 4,960,965 issued Oct. 2, 1990 to Redmon et al. Redmon used carbon fibers in a binder resin for the outer conductive shield. This invention suffers from a lack of performance when the carbon fibers break and cause electrical discontinuities.

Currently, there is a need for a lightweight flexible electronic cable that does not compromise performance.

### SUMMARY OF THE INVENTION

The present invention may be embodied as a method of creating a flexible, lightweight cable comprising the steps of:
a) providing a central conductor [110];
b) growing a thin film dielectric layer [130] of a predetermined thickness on the central conductor [110];
c) processing the dielectric layer [130] with an ion beam; and
d) metalizing the dielectric layer [130] with thin film metalizing technology.
The dielectric layer is metalized with ion beam assisted sputtering technology, evaporative deposition technology or cathodic arc deposition technology.

### OBJECTS OF THE INVENTION

It is an object of the present invention to provide a cable which is lightweight.

It is an object of the present invention to provide a cable which is flexible.

It is another object of the present invention to provide an economically manufactured lightweight cable.

It is another object of the present invention to provide a thinner cable capable of carrying the same signal capacity as thicker prior art cables.

It is another object of the present invention to provide a cable which is much more flexible without sacrificing performance.

### BRIEF DESCRIPTION OF THE DRAWINGS

A complete understanding of the present invention may be obtained by reference to the accompanying drawings, when considered in conjunction with the subsequent detailed description, in which:

FIG. 1 is a perspective view of one embodiment of the cable according to the present invention.

FIG. 2 is a simplified block diagram showing a portion of an apparatus which may be used in implementing the present invention.

FIG. 3 is a diagram of one embodiment of a specific metalizing apparatus for applying a metal coating to a continuous line according to one embodiment of the present invention.

FIG. 4 is an illustration of the major components used in an electrophoretic deposition device according to one embodiment of the present invention.

FIG. 5 is a diagram of one embodiment of a specific metalizing apparatus 300 for applying a metal coating to a continuous line.

FIGS. 6a-6e show cross-sectional views of an alternative embodiment of the cable according to the present invention.

### DETAILED DESCRIPTION OF THE PRESENT INVENTION

### Multilayer Cable Design & Method of Manufacturing

The present invention results in lightweight, flexible wires and cables designed for low signal loss for their individual applications. These wire or cables may be embodied as a coaxial cable with central conductor, a pair of wire conductors, ribbon cables with many conductors and other known cable designs.

Traditionally, the design of electronic cables involved a trade-off between the electrical properties such as high signal propagation and low attenuation and the mechanical or bending properties of the cable.

The present invention results in multilayer cables designed to reduced weight but retain their electrical and mechanical performance properties.

The present invention combines several areas of innovative micro-fabrication technologies in a novel design. The cables are manufactured using thin film technology.

I. Thin Film Continuous Outer Conductor

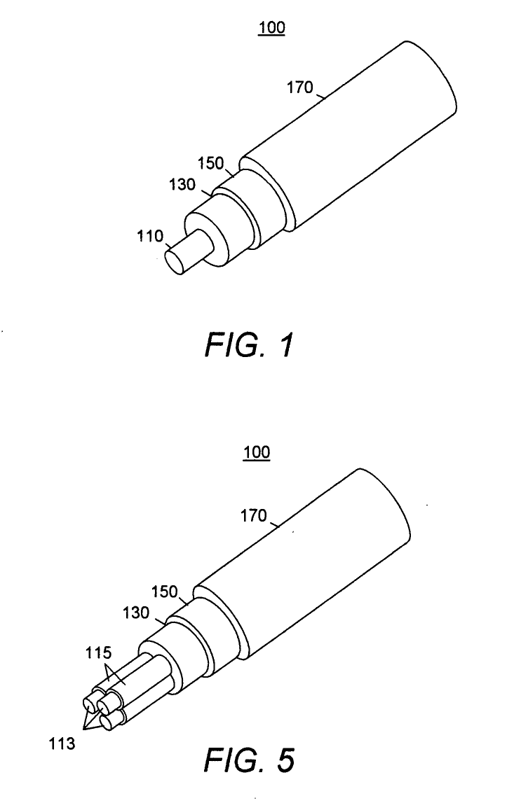

FIG. 1 is a perspective view of one embodiment of the cable 100 according to the present invention.

It is comprised of a central conductor 110 which may be a solid or hollow metal core. An insulating dielectric layer 130 surrounds the central core 110.

Typically, these dielectric layers may include but are not limited to: PTFE, expanded PTFE, Porous PTFE, PFA, polyethylene, poly propylene and other commonly used dielectric materials.

The outer conductor 150 is a thin layer of metallic shielding applied using ion beam assisted deposition. In ion beam assisted deposition a plasma beam bombards surfaces of the substrate to remove oxides and other functional groups before or during deposition of thin film materials to the substrate. Ion beam assisted deposition provides atomic mixing of metal ions and others with immediate atomic structure of substrate materials upon exposure to deposition source. Due to this unique characteristic of this process, the dielectric layer 130 of cable 100 is preprocessed by application of the ion beam, then coating with metal using thin film deposition technology. An apparatus for ion beam preparation of a surface of a substrate intended to be coated with a thin film material is described in U.S. Pat. No. 5,558,718 Leung issued Sep. 24, 1996. This, or a similar apparatus may be used to process the surface and aid in metalizing the dielectric layer.

The dielectric layer 130 may be metalized using various methods including sputtering, evaporation deposition and cathodic arc deposition.

The ion assisted sputtering can be ion-assisted deposition with hollow cathode sputtering. Under this process Copper and Titanium are sputtered circumferentially from the circular target, instead of planner rectangular target used in conventional sputtering. The rectangular target is curved into a cylindrical shape and the substrate (cable 100) passes through an opening in the center of the target. Therefore cable 100 will be coated from every direction while it is moving through the central opening.

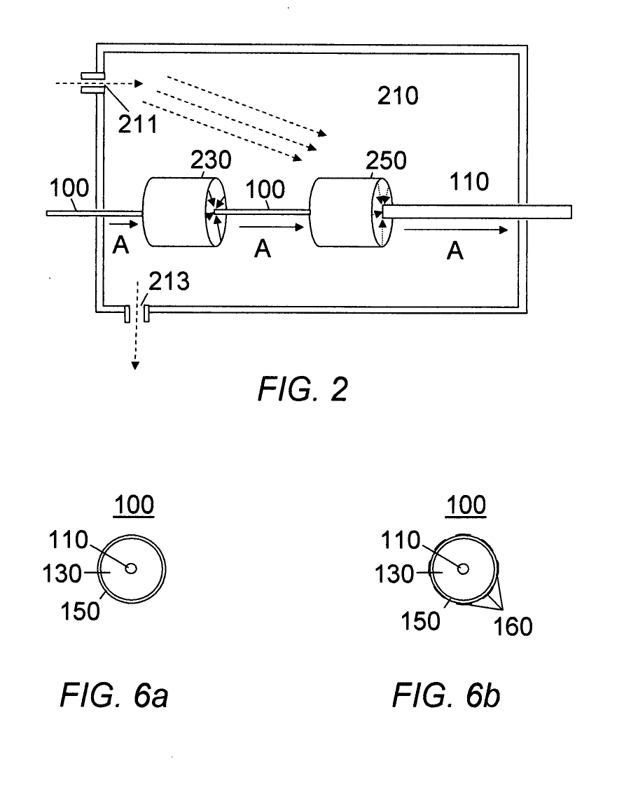

For cables, preprocessing and coating may be a sequential but continuous process as shown in a general sense in FIG. 2. Here a vacuum chamber 210 has a controlled gas inlet 211 and a controlled outlet 213. A substrate, here being cable 100, enters from the left side and passes through a cylindrical plasma ion beam source 230 in the direction of the arrow marked “A”. Plasma ion beam source 230 is cylindrically shaped and designed to preprocess the cable 100 around its circumference as it passes through the plasma ion beam source 230.

Cable 100 moves according to the arrow marked “A” and enters deposition unit 250. Deposition unit 250 applies a thin film material on cable 100. This is designed to be cylindrical and deposits material around the entire perimeter of cable 100 as it passes through deposition unit 250 creating a metalized cable which can be used as a conductor 110.

Deposition unit 250 may apply the thin film using sputtering, evaporation deposition, cathodic arc deposition, or other known method. Conductor 110 continues to move in the direction of the arrow marked “A” out of the vacuum chamber 210.

This deposition unit 250 employs a gas inlet 211 which allows gas to enter in a controlled manner. Spent gases exit through outlet 213.

It is also possible to employ the ion beam bombardment of a substrate at the same time as thin film deposition. For example thin film deposition may be accomplished by a) ion beam assisted sputtering, b) ion beam assisted evaporation deposition and c) ion beam assisted cathodic arc deposition.

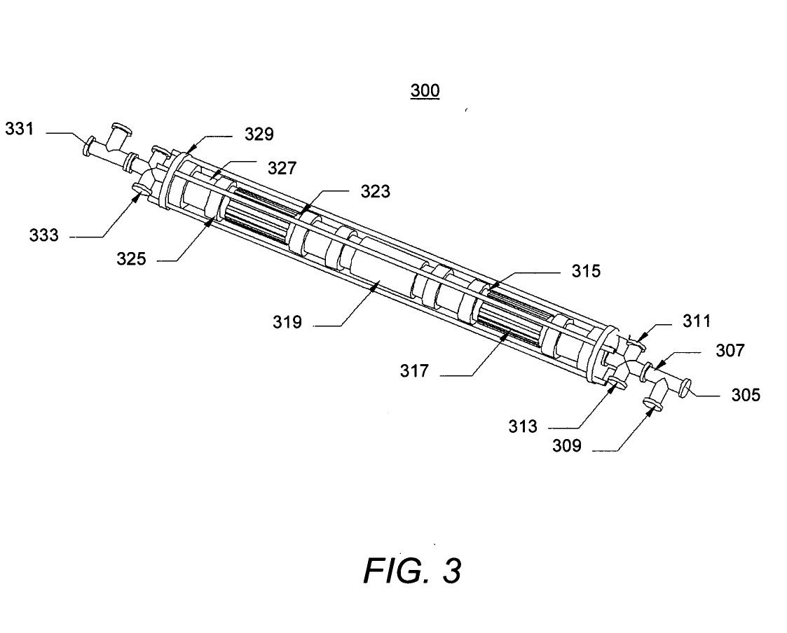

FIG. 3 is a diagram of one embodiment of a specific metalizing apparatus 300 for applying a metal coating to a continuous dielectric cable 100. Cable 100 enters metalizing apparatus 300 at line inlet 305.

Since metalizing apparatus 300 functions in a vacuum environment, quad rings 307 provide an airtight seal around the line. A mechanical vacuum pump (not shown) attaches to rough pump outlet 309 to evacuate the majority of the air in metalizing apparatus 300.

Another vacuum pump (which may be a cryogenic vacuum pump) attaches to hi vac pump outlet 313. A titanium target 315 encircles the line.

A moveable magnet pack 319 provides a magnetic field over the inside of metalizing apparatus 300. The magnetic pack 319 may slide over the titanium target 315, or slide over a copper target 323 which encircles the line. 4 anodes also encircle the line.

Metalizing apparatus may function to preprocess the surface of dielectric cable 100 by etching off hydrogen from molecules comprising the dielectric material of cable 100. These are replaced with other compounds which may include oxygen or nitrogen on the surface of the cable 100. A gas, such as argon is added through gas inlet 333. The gas is turned into plasma which facilitates etching (or preprocessing) of cable surface 100.

With the magnet 319 positioned over the titanium target 315, titanium is deposited on the surface of cable 100.

With the magnet 319 positioned over copper target 323, copper is coated over the titanium on the cable 100 creating the metalized conductor 110.

This two-phase approach allows the copper to adhere to the titanium which adheres to the dielectric material of cable 100. The titanium coating can typically be about 500 Angstroms in thickness. The Copper coating can range from 200 angstroms to 20,000 Angstroms.

In alternative embodiments, a target comprising one or more titanium alloys, chromium or chromium alloys may be used in place of titanium target 315. Other “adhesion promoters” may also be used.

Electrical insulators 325 separate the targets from the anodes 327.

An end flange 329 caps the metalizing apparatus 300.

Cable 100 is coated with a metal layer to create one type of conductor 110. Conductor 110 exits the metalizing apparatus 300 at a wire outlet 331.

The metal coating thickness deposited by the present invention may be from 500 Angstroms up to 50,000 Angstroms. This coatings process can be done either as a batch process or alternatively as a reel to reel continuous coating.

This method may also be used to apply the thin film outer conductor 150 to dielectric layer 130.

Another apparatus which may be used for ion beam assisted sputtering for metalizing substrates is described in U.S. Pat. No. 6,843,891 B2 issued Jan. 18, 2005 to Kahn et al.

Adoption of this process ensures us the outstanding adhesion of thin layer conductor coating on dielectric part of the cable designed for shielding and hence provides substantial weight reduction in cable design.

These processes also provide outstanding adhesion of metals ions and other thin film materials to any desired substrate materials.

II. Dielectric Coating of Central Conductor

In applications in which the voltage difference between the conductors of a multi-conductor cable is small, or the power carried is small, the dielectric layer 130 may be reduced without significant loss of signal. Chemical vapor deposition (“CVD”) may be used to apply the dielectric layer.

Ion beam technology described above may be applied to a substrate to preprocess the surface and assist CVD of a dielectric coating onto a central conductor.

In this case, cables may be ‘grown’ to a specified thickness to fit its specific use.

The ion beam bombards the central insulator with an ion beam to pre-process the surface of the central insulator before the CVD. This causes the dielectric applied by CVD to adhere to the central conductor.

The ion beam may also be used concurrently with the CVD process to cause the dielectric to stick to, and impregnate the central conductor and the dielectric layer 130 already applied to the central conductor 110.

This process can provide 0.10-50 micron thick dielectric coating, including but not limited to oxides, nitrides materials for insulation purposes applicable to cable design.

Furthermore, CVD of fluorocarbon specifically by thermal decompositions of Hexafluropropylene can produce thin film of Teflon® like coating which can be used alternatively for elimination of inductance in cable design as well.

Electrophoretic deposition (“EPD”) may also be used to apply dielectric coating to the cables. Electrophoretic deposition (“EPD”) is a process in which colloidal particles suspended in a liquid medium migrate under the influence of an applied electric field to an electrode. This process is applicable to charged molecules which can produce a stable suspension. The process is useful for applying coating materials to electrically conductive surfaces.

In one embodiment, nano-particles of dielectric materials are suspended in an aqueous emulsion solution to apply the dielectric coating to the cables. This coating is formed by migration of the charged dielectric nano-particles under the application of an electric field. This dielectric coating with its optimum and tunable structure (by the addition of the type and amount of nano-particles) will posses the desired electrical properties, including, but not limited to, an optimum dielectric constant and tangential loss which can be optimized for certain desired frequency applications.

In different embodiments of the present invention, the nano-particles may be nano-sized diamonds. These alter the dielectric properties of various materials and are effective with the present invention. Any of several known processes may be used to synthesize these particles.

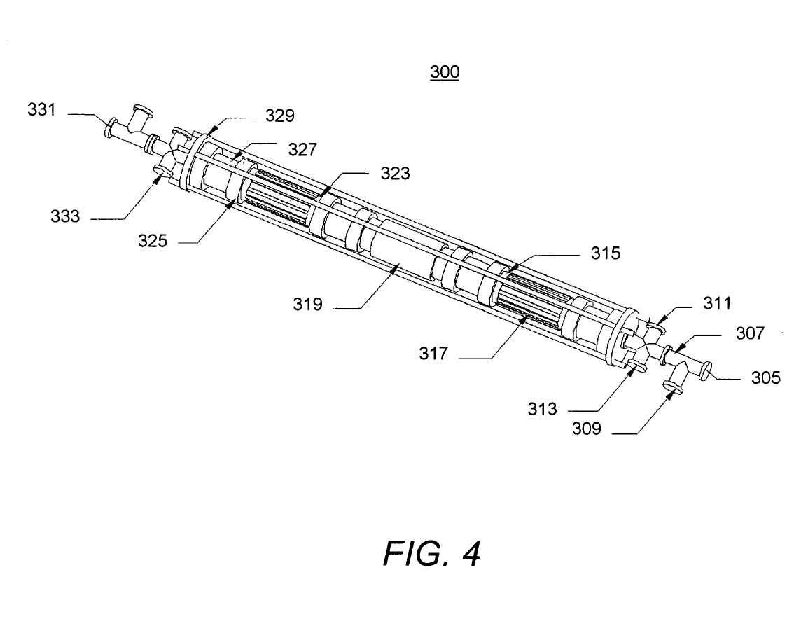

FIG. 4 is an illustration of the major components used in electrophoretic deposition device 400. A wire feed spool 410 has a wire 110 intended to be coated with a dielectric coating. This may be central conductor 110 of FIG. 1.

Conductor 110 passes into a colloidal suspension 421 in a bath 420. The colloidal suspension includes nano-particles. In a preferred embodiment, these nano-particles are nano-diamonds which may have attached functional groups. A circulation pump 423 circulates the suspension to insure even consistency.

Conductor 110 is directed around a roller 425 and through a baffle 427.

Conductor 110 then passes through an annular anode 429 (shown here in cross section). The anode provides an electric field which causes the particles and/or nano-particles in suspension to attach to conductor 110 to create an emulsion coated wire 121.

The emulsion coated wire 121 is then rinsed by rinse nozzle 431. The rinse may include water or other rinsing solution. Excess coating falls off into a catch container 433.

The emulsion coated wire 121 then passes through a curing oven 440. Curing oven operates at an appropriate temperature to cause curing of the coating to create a coated wire 123. This is similar to central conductor 110 and coating 130 of FIG. 1.

U.S. Pat. No. 4,376,031 Andrus et al. issued Mar. 8, 1983 also describes an EPD apparatus which may be used with the present invention to apply coatings.

For integrated cable manufacturing, dielectric coating with different dielectric properties will be deposited on cable parts using water based emulsions and EPD. These may include Flouropolymer base materials.

This process could provide single layer or multilayer dielectric coating composite structures which are capable of improving the overall electrical performance of the cables at any desired operational frequencies. This EPD deposition could provide 1-500 Micron dielectric coatings in multiple layer or single layer coatings.

III. Metal-Coated Dielectric Central Core

Extra weight reduction can be achieved by replacing the solid central conductors (110 of FIG. 1.) in coaxial cable design with dielectric fibers 113 having a metal layer 115. In FIG. 5, it can be seen that the central conductor (110 of FIG. 1) has been replaced with a plurality of dielectric polymers, glass or composite fibers 113. Dielectric fibers 113 are metalized using the techniques described above to add a metal layer as an outer conductor 150 to the dielectric layer 130. Since dielectric fibers 113 are strong and flexible, and since metal layer 115 is very thin and flexible, the resulting cable 100 is very light and flexible without significant signal attenuation.

IV. Fire Retardant Coating

Since there is the consideration of electrical short circuits causing heat and possibly fires in wiring, the present invention employs a fire retardant coating. In FIGS. 1 and 3, the outer coating 170 can be made from a fire retardant coating 170. Electrophoretic deposition described above may be used to apply this coating.

V. Magnetic Shielding

Furthermore, this technique provides the opportunity to deposit multilayer composite structure, including, but not limited to, thin-film magnetic materials for magnetic shielding of electromagnetic signals as well.

U.S. Pat. No. 6,846,985 B2 issued Jan. 25, 2005 to Wang et al. describes construction of a magnetic shield which may be added to the cables described above. This results in a lightweight, flexible cable which has additional magnetic shielding properties.

VI. Electrophoretic Deposition of Photoimagable Formulation

Electrophoretic deposition may be used to apply photoimagable water based emulsion on the outer conductor 150 of FIG. 1 or 5. This provides the possibilities of using Lithographical technology for creating patterns on the outer conductor 150.

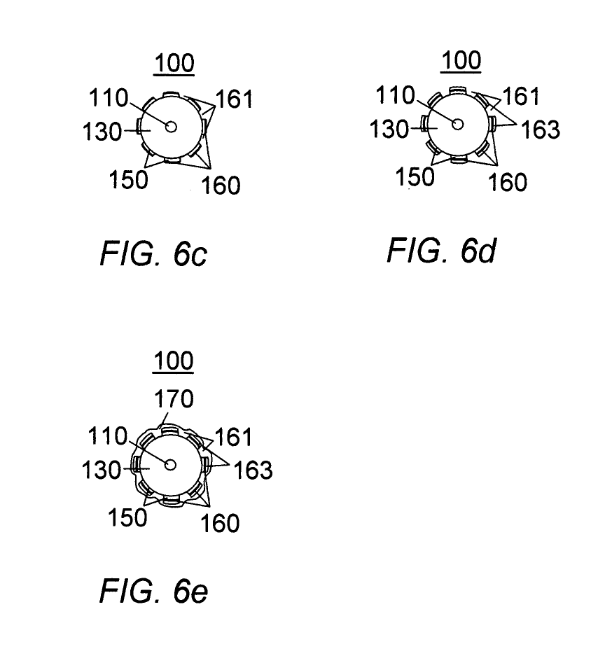

FIG. 6a shows a cross section of an embodiment of the light weight cable 100 of FIG. 1 without its outer coating 170. This is shown having the central conductor 110 and a dielectric layer 130. It has a metalized layer as an outer conductor 150.

In FIG. 6b photoimageable mask 160 is bonded to outer conductor 150 using known lithographic technology.

In FIG. 6c, portions of outer conductor 150 which were not covered by photoimagable mask 160 are etched away leaving gaps 161. By properly etching enough of the outer conductor away, there is less ‘bunching’ of the outer conductor 150 as the cable is bent, further increasing flexibility and reducing weight. This also allows construction of miniaturized cables with conductors in pattern format.

VII. Electrophoretic Deposition of Piezo-Transducer Sensors

An alternative embodiment of the present invention would be piezoelectric transducer cables as shown in FIGS. 6d and 6e.

The EPD process is used to apply a piezoelectric layer to outer conductor 150 prior to the etching process.

U.S. Pat. No. 5,810,009 Mine et al. issued Sep. 22, 1998 describes the process of attaching piezoelectric material to a thin cable to produce piezoelectric cable transducers.

The cable appears as shown in FIG. 6d after the etching showing the piezoelectric layer 163.

EPD may then be used to provide an electrical insulating coating 170 to cable 100 as shown in FIG. 6e. The application of this process provides cables 100 capable of acting as piezoelectric sources and sensor arrays for ultrasonic imaging use.

Advantages:

The innovative manufacturing methods exhibit the following desirable features:

weight reduction of 50% or more
controlled shield thickness tuning
shielding depth optimized for end use
fire retardant properties
flexible central core
customized cables tailored to each specific need
incorporation of patterned conductors incorporation of piezoelectric transducer into the thin cable design

Even though the example used above focused on a coaxial cable, any number of other arrangements, such as flat wires, ribbon cable or multiple conductor cable having other geometries may be manufactured with the present invention.

While several presently preferred embodiments of the novel invention have been described in detail herein, many modifications and variations will now become apparent to those skilled in the art.

What is claimed is:

1. A method of creating a flexible, light weight cable comprising the steps of:
a) providing a central conductor [110];
b) growing a thin film dielectric layer [130] to the central conductor [110];
c) processing the dielectric layer [130] with an ion beam; and
d) metalizing the dielectric layer [130] with thin film metalizing technology.

2. The method of claim 1, wherein the central conductor [110] is a solid metal conductor.

3. The method of claim 1, wherein the central conductor [110] is a hollow metal conductor.

4. The method of claim 1, wherein the central conductor [110] is comprised of dielectric strands that are metalized.

5. The method of claim 1, wherein the step of metalizing includes metalizing with sputtering technology.

6. The method of claim 1, wherein the step of metalizing includes metalizing with evaporative deposition technology.

7. The method of claim 1, wherein the step of metalizing includes metalizing with cathodic arc deposition technology.

8. The method of claim 1, wherein the dielectric layer is grown to a desired thickness using electrophoretic deposition.

9. The method of claim 1, wherein the dielectric layer includes nano-diamond particles.

10. The method of claim 1, wherein the dielectric layer includes nano-graphite particles.

11. The method of claim 1, further comprising the step of:
a) adding a photoimageable mask [160] on a portion of the outer conductor; and
b) etching away the outer conductor [150] in regions which have no photoimageable mask [160] to result in a more flexible outer conductor [150].

12. The method of claim 1, further comprising the step of:
a) adding a photoimageable mask [160] on a portion of the outer conductor;
b) coating the outer conductor [150] with a piezoelectric layer [163] and
c) etching away the piezoelectric layer [163] and outer conductor [150] in regions which have no photoimageable mask [160] to result in a piezoelectric transducer cable.

13. A flexible, lightweight cable comprising:
a) a central conductor [110];
b) a thin film dielectric layer [130] coating the central conductor [110] having its surface process with an ion beam; and
c) a thin film metal coating covering the dielectric layer [130] applied with thin film metalizing technology.

14. The cable of claim 13, wherein the central conductor [110] is a solid metal conductor.

15. The cable of claim 13, wherein the central conductor [110] is a hollow metal conductor.

16. The cable of claim 13, wherein the central conductor [110] is comprised of dielectric strands that are metalized.

17. The cable of claim 13, wherein the thin film metal coating is created with sputtering technology.

18. The cable of claim 13, wherein the thin film metal coating is created with evaporative deposition technology.

19. The cable of claim 13, wherein the thin film metal coating is created with cathodic arc deposition technology.
